(19) United States
(12) Patent Application Publication
(10) Pub. No.: US 2017/0126239 A1
(43) Pub. Date: May 4, 2017

(54) NOISE-SHAPING SUCCESSIVE-APPROXIMATION-REGISTER ANALOG-TO-DIGITAL CONVERTER

(71) Applicant: BOARD OF REGENTS, THE UNIVERSITY OF TEXAS SYSTEM, Austin, TX (US)

(72) Inventors: Nan Sun, Austin, TX (US); Wenjuan Guo, Austin, TX (US)

(21) Appl. No.: 15/343,446

(22) Filed: Nov. 4, 2016

Related U.S. Application Data
(60) Provisional application No. 62/250,709, filed on Nov. 4, 2015.

(51) Int. Cl. H03M 1/08; H03M 1/46

(52) U.S. Cl. CPC H03M 1/08; H03M 1/46

(57) ABSTRACT

Disclosed herein are systems and methods that describe a noise-shaping (NS) SAR architecture that can be simple, effective, and low power. In an aspect, a method includes the operation of receiving a first analog input; determining a first digital output based on the first analog input; obtaining a first quantization error for the first digital output; integrating the first quantization error; receiving a second analog input; and determining a second digital output based on the summation of the second analog input and the first integrated quantization error to perform noise-shaping.

### CROSS-REFERENCE TO RELATED APPLICATION

This application claims priority to, and the benefit of, U.S. Provisional Application No. 62/250,709, filed Nov. 4, 2015, titled “Fully-Passive Reconfigurable Noise-Shaping SAR ADCs”, which is incorporated by reference herein in its entirety.

### BACKGROUND

Analog-to-digital converters (commonly referred to as ADCs, A/Ds, or A to Ds) can refer to devices that convert a continuous physical quantity (such as voltage) to a digital number that can represent the quantity's amplitude. The result can be a sequence of digital values that have been converted from a continuous-time and continuous-amplitude analog signal to a discrete-time and discrete-amplitude digital signal. Additionally, the conversion can involve quantization of the input that can lead to the introduction of a small amount of error.

Quantization error can refer to the noise introduced by quantization in an ideal ADC. It can refer to a rounding error between the analog input voltage to the ADC and the output digitized value. These errors can be measured in a unit called the least significant bit (LSB). For example, in an eight-bit ADC, an error of one LSB is 1/256 of the full signal range, or about 0.4%.

The dynamic range of an ADC can be summarized in terms of its effective number of bits (ENOB). An ideal ADC can have an ENOB equal to its resolution. However, a real ADC can have noise and distortion, which can make its ENOB lower than its resolution.

A successive-approximation register (SAR) ADC can refer to an ADC that uses a comparator to successively narrow a range that contains the input voltage. At each successive step, the converter can compare the input voltage to the output of an internal digital to analog converter (commonly referred to as a DAC, D/C, or D to A) which can represent the midpoint of a selected voltage range. At each step in this process, the approximation can be stored in a successive approximation register (SAR) or other type of memory.

For medium-resolution applications, SAR ADCs are a popular choice due to their high power efficiency in nanometer technology. However, as the target resolution goes beyond 10-bit, SAR ADCs' efficiency may quickly diminish due to their tight requirement on comparator noise. Moreover, the exponentially increasing capacitor DAC array that many SAR ADCs employ may not only costs large chip area and power, but can also makes it difficult to drive. For high-resolution applications, Delta-Sigma (ΔΣ) ADCs offer a more widely-used architecture. Taking advantage of oversampling and noise shaping, they can use a low-resolution quantizer to reach high resolution. Nevertheless, ΔΣ ADCs can require operational transconductance amplifiers (OTAs) which are power hungry and can be less amenable to scaling.

There have been emerging efforts to develop hybrid ADC architectures that combine the merits of SAR and ΔΣ ADCs. The first noise-shaping (NS) SAR ADC was published in J. Fredenburg, et al., “A 90 MS/s 11 MHz Bandwidth 62 dB SNDR Noise-Shaping SAR ADC,” ISSCC Dig. Tech. Papers, pp. 468-470, 2012 (incorporated by reference herein in its entirety). However, it still needed an active OTA-based integrator to realize a noise transfer function (NTF) zero at approximately 0.64. It also required a finite-impulse-response (FIR) DAC, which introduces extra noise and increases chip area. Later, a fully-passive NS-SAR ADC was published in Z. Chen, et al., “A 9.35-ENOB, 14.8 fJ/conv.-step Fully-Passive Noise-Shaping SAR ADC,” IEEE VLSI Symp. Circuits, pp. C64-C65, 2015 (incorporated by reference herein in its entirety). It obviates the need for OTAs, but its noise-shaping performance is limited, as its NTF zero is located at approximately 0.5 rather than approximately 1. Moreover, its input signal is attenuated by approximately 2 times during normal conversion, leading to an approximately 6-dB penalty in SNR or approximately quadrupled analog power for the same SNR. In addition, it requires approximately 2-time more capacitance, increasing chip area.

Therefore, what are needed are devices, systems and methods that overcome challenges in the present art, some of which are described above.

### SUMMARY

Disclosed herein are systems and methods that describe a noise-shaping (NS) SAR architecture that can be simple, effective, and low power. In one aspect, the disclosed systems and methods do not require any active components such as operational transconductance amplifiers (OTAs). Furthermore, the disclosed systems and methods cause negligible signal attenuation, and can use passive components requiring less capacitance than previous works. The disclosed systems and methods can be amenable to modification to the original SAR ADC, and can allow easy reconfiguration between the conventional Nyquist mode and the ΔΣ NS mode of operation. In one aspect, the disclosed NS SAR ADC can shape the quantization noise, comparator noise, and DAC noise. Moreover, it can allow the use of a low-resolution DAC and can relax the requirement on comparator noise, making it possible to simultaneously achieve high-resolution and high-power efficiency operation.

In an aspect, a method for noise shaping (e.g., first order, second order, and etc.) in a noise shaping successive approximations register analog-to-digital converter (NS SAR ADC) is described. The method includes: receiving a first analog input; determining a first digital output based on the first analog input; obtaining a first quantization error for the first digital output; integrating the first quantization error; receiving a second analog input; and determining a second digital output based on the summation of the second analog input and the first integrated quantization error to perform noise-shaping. In some embodiments, the method further allow for the reconfiguration between a Nyquist mode and a ΔΣ NS mode of operation.

In some embodiments, the step of receiving the first and second analog inputs includes sampling the analog inputs using bottom-plate sampling. In some embodiments, the step of performing noise shaping realizes a noise transfer function (NTF) zero at a predetermined value. In some embodiments, the NTF is determined in part by user configurable parameters to make the NS SAR ADC insensitive to process, voltage, temperature (PVT) variations. In some embodiments, the step of performing noise shaping includes shaping a quantization noise, a comparator noise, and a DAC noise. In some embodiments, a mode signal is used to reconfigure the ADC between a Nyquist mode and a ΔΣ NS mode. In some embodiments, the NS SAR ADC is made, in whole, or in part, from complementary metal-oxide-semiconductor (CMOS) technology.

In another aspect, a system for noise shaping in a NS SAR ADC is described. The system includes: a capacitor array (e.g., a binary weighted capacitor array); a multi-path comparator (e.g., a two-path comparator, a three-path comparator, a four-path comparator, and n-path comparator); and a passive integrator with two or more capacitors. The binary weighted capacitor array is configured to receive a first analog input; the two-path comparator is configured to determine a first digital output based on the analog input and feed the first digital output to the capacitor array to obtain a first quantization error; the passive integrator with two capacitors is configured to integrate the first quantization error for the first digital output to produce a first integrated quantization error; the binary weighted capacitor array is configured to receive a second analog input; and the two-path comparator is configured to determine a second digital output based on a summation of the second analog input and the first integrated quantization error to perform noise shaping. The system further can allow for the reconfiguration between a Nyquist mode and a ΔΣ NS mode of operation. Moreover the NS SAR ADC can be made from complementary metal-oxide-semiconductor (CMOS) technology.

In some embodiments, the operation of the system to receive the first and second analog inputs includes sampling the analog signal using bottom-plate sampling. In some embodiments, the operation of the system to perform noise shaping realize a noise transfer function (NTF) zero at a predetermined value. In some embodiments, the NTF is determined in part by user configurable parameters to make the NS SAR ADC insensitive to PVT variations. In some embodiments, the operation of the system to perform noise shaping includes shaping a quantization noise, a comparator noise, and a DAC noise. In some embodiments, a mode signal is used to reconfigure the ADC between a Nyquist mode and a ΔΣ NS mode.

In another aspect, a method is disclosed of operating a noise-shaping (e.g., second-order) successive-approximations-register analog-to-digital converter (NS SAR ADC). The method includes receiving a first analog input; determining a first digital output based on the first analog input; obtaining a first quantization error for the first digital output; integrating the first quantization error to generate a first integrated quantization error; integrating the first integrated quantization error to generate a second integrated quantization error; receiving a second analog input; and determining a second digital output, via noise-shaping, based on the summation of the second analog input, the first integrated quantization error, and second integrated quantization error. In some embodiments, the first and second integration step are each performed via a passive integrator. In some embodiments, the process of determining a second digital output is performed via a 3-path comparator circuit.

Additional advantages will be set forth in part in the description which follows or may be learned by practice. The advantages will be realized and attained by means of the elements and combinations particularly pointed out in the appended claims. It is to be understood that both the foregoing general description and the following detailed description are exemplary and explanatory only and are not restrictive, as claimed.

### BRIEF DESCRIPTION OF THE DRAWINGS

The accompanying drawings, which are incorporated in and constitute a part of this specification, illustrate embodiments and together with the description, serve to explain the principles of the methods and systems:

FIG. 1A shows a flow chart diagram in accordance with the methods and systems described herein;

FIG. 1B shows a representative circuit diagram in accordance with an exemplary aspect of the disclosed systems and methods;

FIG. 2 shows the general signal flow diagram of the representative circuit diagram of FIG. 1B;

FIG. 3 shows the general signal flow diagram as in FIG. 2 with non-ideal effects such as thermal noises and DAC mismatch errors;

FIG. 4, comprising FIGS. 4A and 4B, shows a prototype first-order NS SAR ADC which is fabricated in an approximately 130 nm complementary metal-oxide-semiconductor (CMOS) process with a core area of approximately 0.13 mm².

FIG. 5, comprising FIGS. 5A and 5B, shows the measured output spectrum of the NS SAR ADC with an approximately 95.37 KHz, and approximately −2 dBFS sinusoidal input;

FIG. 6, comprising FIGS. 6A and 6B, shows the measured SNR/SNDR trends of the NS SAR ADC with different oversampling ratios (OSRs) and input amplitudes in the ΔΣ NS mode of operation;

FIG. 7 shows a table summarizing chip performance for the example NS SAR ADC discussed in relation to FIG. 4;

FIG. 8 shows a representative circuit diagram for a second-order NS SAR ADC in accordance with an exemplary aspect of the disclosed systems and methods;

FIG. 9 shows a general signal flow diagram of the representative circuit diagram of FIG. 8;

FIG. 10 shows the general signal flow diagram as in FIG. 9 with non-ideal effects such as thermal noises and DAC mismatch errors;

FIG. 11 shows a simulated output spectra of a second-order NS SAR ADC; and

FIG. 12, comprising FIGS. 12A and 12B, shows the simulated SNDR/Schreier FoM (FoM_{S})/Walden FoM (FoM_{W}) trend with different OSRs.

### DETAILED DESCRIPTION

Before the present methods and systems are disclosed and described, it is to be understood that the methods and systems are not limited to specific synthetic methods, specific components, or to particular compositions. It is also to be understood that the terminology used herein is for the purpose of describing particular embodiments only and is not intended to be limiting.

As used in the specification and the appended claims, the singular forms “a,” “an” and “the” include plural referents unless the context clearly dictates otherwise. Ranges may be expressed herein as from “about” one particular value, and/or to “about” another particular value. When such a range is expressed, another embodiment includes [symbol] from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other additives, components, integers or steps. “Exemplary” means “an example of” and is not intended to convey an indication of a preferred or ideal embodiment. “Such as” is not used in a restrictive sense, but for explanatory purposes.

Disclosed are components that can be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific embodiment or combination of embodiments of the disclosed methods.

The present methods and systems may be understood more readily by reference to the following detailed description of preferred embodiments and the Examples included therein and to the Figures and their previous and following description.

As will be appreciated by one skilled in the art, the methods and systems may take the form of an entirely hardware embodiment, an entirely software embodiment, or an embodiment combining software and hardware aspects. Furthermore, the methods and systems may take the form of a computer program product on a computer-readable storage medium having computer-readable program instructions (e.g., computer software) embodied in the storage medium. More particularly, the present methods and systems may take the form of web-implemented computer software. Any suitable computer-readable storage medium may be utilized including hard disks, CD-ROMs, optical storage devices, or magnetic storage devices.

Embodiments of the methods and systems are described below with reference to block diagrams and flowchart illustrations of methods, systems, apparatuses and computer program products. It will be understood that each block of the block diagrams and flowchart illustrations, and combinations of blocks in the block diagrams and flowchart illustrations, respectively, can be implemented by computer program instructions. These computer program instructions may be loaded onto a general purpose computer, special purpose computer, or other programmable data processing apparatus to produce a machine, such that the instructions which execute on the computer or other programmable data processing apparatus create a means for implementing the functions specified in the flowchart block or blocks.

These computer program instructions may also be stored in a computer-readable memory that can direct a computer or other programmable data processing apparatus to function in a particular manner, such that the instructions stored in the computer-readable memory produce an article of manufacture including computer-readable instructions for implementing the function specified in the flowchart block or blocks. The computer program instructions may also be loaded onto a computer or other programmable data processing apparatus to cause a series of operational steps to be performed on the computer or other programmable apparatus to produce a computer-implemented process such that the instructions that execute on the computer or other programmable apparatus provide steps for implementing the functions specified in the flowchart block or blocks.

Accordingly, blocks of the block diagrams and flowchart illustrations support combinations of means for performing the specified functions, combinations of steps for performing the specified functions and program instruction means for performing the specified functions. It will also be understood that each block of the block diagrams and flowchart illustrations, and combinations of blocks in the block diagrams and flowchart illustrations, can be implemented by special purpose hardware-based computer systems that perform the specified functions or steps, or combinations of special purpose hardware and computer instructions.

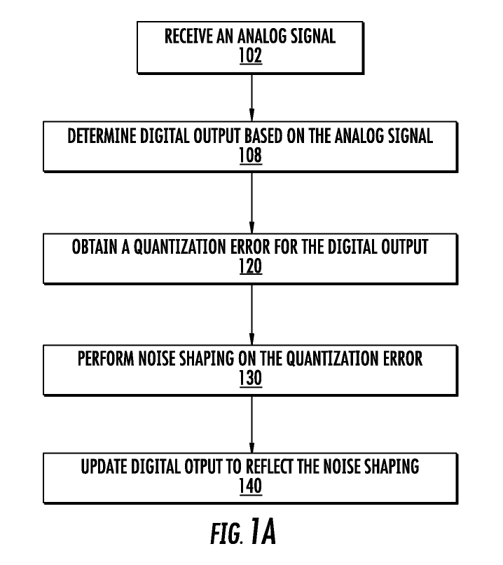

FIG. 1A is a flow chart illustrating a method of noise shaping (NS) for an exemplary SAR ADC. FIG. 1B shows an exemplary circuit for the noises-shaping successive-approximation-register analog-to-digital converter (NS SAR ADC) 100, which can be used for implementation of the method shown in FIG. 1A.

Referring first to FIG. 1B, compared to conventional SAR operation, two more clock cycles, Φₙₛ₀ and Φₙₛ₁, are used. Before the Φₙₛ₀ cycle, the SAR ADC does a normal conversion. To realize a 1st-order noise shaping, the residual voltage Vᵣₑₛ (e.g., 118) is integrated and fed, via feedback, to the comparator input. During Φₙₛ₀ cycle (e.g., when Φₙₛ₀ switch 117 is closed), charge of a small capacitor (shown as “C2=C/3” 122) is merged with charges of DAC capacitors (shown as “C1=C” 119a, 119b to 119n), to produce the residue voltage, Vᵣₑₛ (118). At the end of Φₙₛ₀ cycle (e.g., when Φₙₛ₀ switch 117 opens), in some embodiments, C2 (122) will carry a charge of 0.75Vᵣₑₛ. In the following Φₙₛ₁ cycle (e.g., when Φₙₛ₁ switch 123 is closed), C2 (122) dumps its charge onto another capacitor (shown as “C3=C” 124)—effectively realizing a passive integration. The voltage integrated on C3 (122) is labelled as Vᵢₙₜ (126), which is fed to the comparator input (e.g., of comparator 140). As shown, the comparator 140 has 2-path inputs, one of which is connected to Vᵣₑₛ (118) and a second connected to Vᵢₙₜ 122. Because passive integration can integrate only a fraction of Vᵣₑₛ (118), which can degrade the noise shaping performance, in some embodiments, a gain (e.g., via a circuit, e.g., an operational transconductance amplifiers) can be used to compensate for the attenuation of Vᵣₑₛ.

In another embodiment, the comparator input transistors (e.g., in comparator 140) can be varied in gain to compensate for the attenuation of Vᵣₑₛ. In some embodiments, because the output of the comparator 140 is a 1-bit sign, the relative gain between Vᵢₙₜ (126) and Vᵣₑₛ (118) can be compared, which can be realized by sizing the comparator input transistors correspondingly. As shown in FIG. 1B, to provide a gain of approximately 4 on the Vᵢₙₜ path (e.g., corresponding to Vᵢₙₜ 126) for a proper NTF, the corresponding input transistors (shown as 126a and 126b) can be designed approximately 4 times larger than those of the Vᵣₑₛ path (e.g., corresponding to Vᵣₑₛ 118). Although the total noise from the comparator input pair may increase in the Vᵣₑₛ path, the impact is negligible to the circuit operation because the in-band comparator noise will be significantly attenuated due to noise shaping. After Φₙₛ₁ cycle (e.g., when Φₙₛ₁ switch 123 opens), the charge on C2 (122) is cleared in next Os cycle to be ready for getting the new residual voltage. In real implementation, a mode signal is used, in some embodiments, to pull down Vᵢₙₜ (126) to ground so that the SAR ADC can be reconfigured to the conventional mode, e.g., in Nyquist-rate applications. Additionally, foreground calibration on DAC mismatch can also be conducted in the Nyquist mode.

Method of Operation

FIG. 1A is now discussed in relation to FIG. 1B. The disclosed method of FIG. 1A includes receiving (operation 102) a first analog input (e.g., Vᵢₙ) by a NS SAR ADC 100. FIG. 1B shows a timing diagram 101 of clock cycles (shown as clock signals, or clock cycles, “Φₑ” 103a, “Φₛ” 103b, “Φ_{c}” 103c, “Φₙₛ₀” 103d, and “Φₙₛ₁” 103e) for the operation of circuit 100. As stated above, compared to conventional SAR operations, two additional clock cycles (for noise-shaping), φₙₛ_{₀} (e.g., 103d) and φₙₛ_{₁} (e.g., 103e), are used. φₛ (e.g., 103b) represents the sampling cycle. Sampled input Vᵢₙ can be sampled by a binary weighed cap array 110. φₑ (e.g., 103a) is another sampling cycle which is earlier than φₛ. This sampling technique, using a switched-capacitor sampling network (e.g., the binary weighted capacitor array 110), is also called bottom-plate sampling. It can be used, in some embodiments, to avoid nonlinear charge injection from the sampling switches 112.

As shown in FIG. 1B, clock cycle φₑ (e.g., 103a) is turned off earlier than clock cycle φₛ (e.g. 103b), which ensures that the charge on the two-path comparator 140 input is conserved. The charge injection from the φₑ switch 116 does not pose a problem (i.e., to the conservation of charge) in this example circuit because the switch 116 is always connected to a common-mode voltage.

Referring still to FIG. 1A, the disclosed method includes determining (operation 108), by the NS SAR ADC 100, a first digital output based on the first analog signal. Referencing FIG. 1B, after a cycle of φₛ occurs (e.g., in 101a), the binary weighted capacitor array 110 can be reconfigured to V_{refp}/V_{refm}. For simplicity, “1” and “0” can be used to represent V_{refp}/V_{refm}. An example initial sequence can be, for ease of explanation, [0, 1, . . . , 1]. This particular sequence can be used to provide a common-mode voltage of ½. Based on charge conservation, the two-path comparator's (140) positive input node Vᵣₑₛ 118 voltage will have a voltage value of ½−Vᵢₙ.

For differential circuits, one side (e.g., Vᵣₑₛₚ) can have a voltage value of ½−Vᵢₙ₊ (for example) while another side (e.g., Vᵣₑₛₘ) can have a voltage value of ½−Vᵢₙ₋. Once switch 142 associated with clock cycle φ_{c} (103c) starts (see 101a and switch 142), the two-path comparator 140 compares ½−Vᵢₙ₊+4Vᵢₙₜₚ with ½−Vᵢₙ₋+4Vᵢₙₜₘ. If ½−Vᵢₙ₊+4Vᵢₙₜₚ>½−Vᵢₙ₋+4Vᵢₙₜₘ, the two-path comparator 140 will yield a result of 1. The result (144) can be fed back to the DAC array 110. Consequently, the positive side DAC array 110 is connected to [1, 1, . . . , 1]. The negative side DAC array 110 stays at [0, 1, . . . , 1]. At this point, the comparator positive input Vᵣₑₛₚ of Vᵣₑₛ 118 has a voltage of 1−Vᵢₙ₊. The negative input Vᵣₑₛₙ of Vᵣₑₛ 118 stays at a voltage value of ½−Vᵢₙ₋. Once the next cycle of φ_{c} (see 101b and 142) starts, the two-path comparator 140 will begin to compare the voltage values of 1−Vᵢₙ₊+4Vᵢₙₜₚ with ½−Vᵢₙ₋+4Vᵢₙₜₘ. This process can continue iteratively to yield all digital outputs.

As described until this point, the NS SAR ADC 100 works like a conventional SAR ADC. As such, there can be many different switching techniques to get the digital outputs from a SAR ADC. Described so far is merely one kind of low power switching technique called bidirectional single-side switching. Different switching techniques (such as monotonic, voltage-common-mode (V_{cm})-based, and split capacitor techniques, among others) can also be used to reconfigure the DAC array 110.

Referring still to FIG. 1A, the disclosed method includes obtaining (operation 120), by the NS SAR ADC, a first quantization error for the first digital output. One property of the NS SAR ADC 100 is that after feeding back all the digital outputs to the DAC array 110, the quantization error (Dₒᵤₜ-Vᵢₙ) remains on the two-path comparator's (140) input 118a. This can also be called the residual voltage (Vᵣₑₛ) 118.

Still referencing FIG. 1A, the disclosed method includes integrating (operation 130), by a NS SAR ADC, the first quantization error. Referencing FIG. 1B, in order to realize noise shaping, previous cycles' Vᵣₑₛ are stored and then fed back to next cycle's input using a passive integrator with two capacitors 121. To this end, during the φₙₛ₀ cycle (see 101), a small capacitor, C₂ (e.g., 122), can be used to get Vᵣₑₛ from the DAC array's (110) C₁. There can be some signal attenuation during this process, but it will not affect the ultimate functionality of the NS SAR ADC 100 because the signal can be gained back later. During φₙₛ₁ (see 101), the small capacitor, C₂ (122) can transfer the voltage to another larger capacitor, C₃ (124). This can essentially realize a passive integration process. C₃ (122) can be connected to the two-path comparator's (140) second-path (e.g., 126) so that in next cycle (see 101), the two-path comparator's (140) determination will consider previous cycles' Vᵣₑₛ 118. Note that the two-path comparator 140 will not work during these two cycles, and rather, only charge transfer happens.

As mentioned, a passive integrator may not be able to provide any gain. As represented in the detailed version of the two-path comparator's (140) internal circuitry, 150, the two-path comparator input transistors (118 and 126) can have a second-path transistor (shown as 126a and 126b) that is sized approximately four times larger than the first-path transistor (shown as 118a and 118b) in order to gain back the signal attenuation due to charger sharing between the capacitors C₁, C₂ and C₃. For completeness, the two-path comparator's (140) internal circuitry 150 also shows the cross-coupled inverters 152 that connect the two input transistors (118 and 126) of the two-path comparator, as well as the switch 142 associated with the input clock signal φ_{c}. One cost can be that the total noise from the two-path comparator's input pair can increase by approximately four times when referred to the Vᵣₑₛ path. Fortunately, the in-band comparator noise can be significantly attenuated due to noise shaping.

Referring back to FIG. 1A, the disclosed method includes receiving a second analog input, and determining a second digital output based on the summation of the second analog input and the first integrated quantization error to perform (operation 140) noise shaping. Referencing FIG. 1B, in next cycle's φₛ (e.g., 101b) (see time diagram 101), the charge on the small capacitor C₂ 122 can be cleared to be ready for determining the new Vᵣₑₛ 118. In one aspect, a mode signal can be used to pull down Vᵢₙₜ (126) to ground so that the NS SAR ADC (100) can be easily reconfigured to the conventional mode for Nyquist-rate applications. The mode signal can be either high (Vdd) or low (ground), and can turn on an N-type metal-oxide-semiconductor logic (NMOS) switch which can pull the two path comparator's two-path inputs to ground when it is high. Additionally, the mode signal can help conduct foreground calibration on DAC mismatch, which will be explained in detail later.

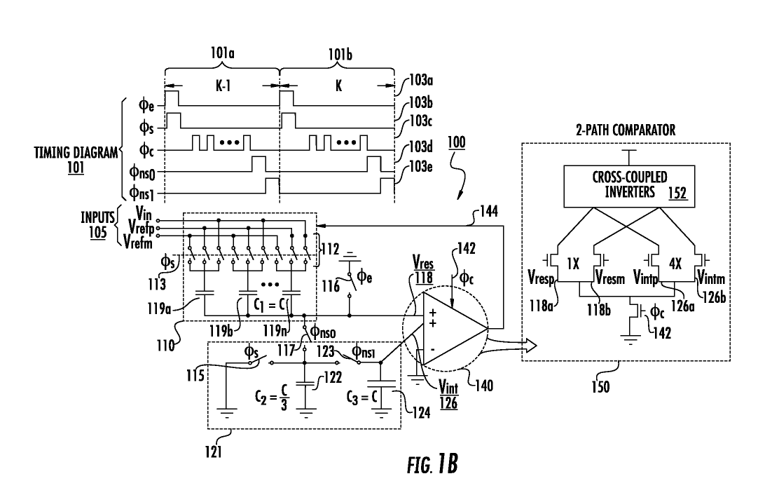

For a more detailed discussion of the disclosed NS SAR ADC architecture, FIG. 2 shows the general signal flow diagram corresponding to the NS SAR ADC circuit (100) of FIG. 1. An input signal Vᵢₙ(z) 200 is amplified by (1−a) in 205. From here, the signal passes to a passive two integrator 210, where the quantization error is integrated. The passive integrator 210 comprises an additional amplification step 210a and a summation step, after which the signal can be relabeled as Vᵢₙₜ(z) 210b, and is delayed and amplified by 210c, and then passed along to the two-path comparator 220. The two-path comparator 220 comprises a first multiplication by g and a delay 220a, after which the original signal Vᵢₙ(z) 200 is added to the signal path. After that the quantization signal 220b is added to the signal path. At this point the signal is fed back to the start of the flow diagram, and the process is repeated. The final result Dₒᵤₜ(z) 230 (Equation 1) will contain Vᵢₙ(z) 200 and noise shaped Q(z) 220b.

Dₒᵤₜ(z)+Vᵢₙ(z)+[1−(1−a)z⁻¹]Q(z) (Equation 1)

For the purposes of this circuit, it can be assumed (approximately) that C₁=C₃=C,

$${C}_{2} = \frac{a}{1 - a} C ,$$

and the integration path gain is approximately g. As can be seen from the derived NTF in the Dₒᵤₜ equation, there is a zero located at approximately (1−a) and a pole located at approximately (1−a)(1−ga). When

$$g = \frac{1}{a} ,$$

(approximate) the pole can be eliminated and the zero remains. As mentioned, in this design, a=¼ and g=4 (approximate), giving a NTF of approximately (1−0.75z⁻¹).

Also gain g can be chosen such that g>4 (approximate), in order to get a negative pole which can help improve the NS performance of the NS ADC SAR. However, since the two-path comparator's noise (or power) increases with the value of gain g, the overall benefit may be limited. With a=¼ (approximate), the C₂ value is approximately C/3 and consequently only approximately 4/3 times more capacitors are required for first-order NS. Note that the NTF can be completely determined by component ratios a and g, and thus, can be insensitive to process, voltage, temperature (PVT) variations.

To ensure stability, the pole are placed within the unit circle. The stability condition is shown in FIG. 2. Given that the current stability condition is 4/3<g<28/3 (approximate), g=4 (approximate) determined by the two-part comparator's input transistor ratio is far from the unstable boundary. Therefore, the disclosed NS SAR architecture is highly robust.

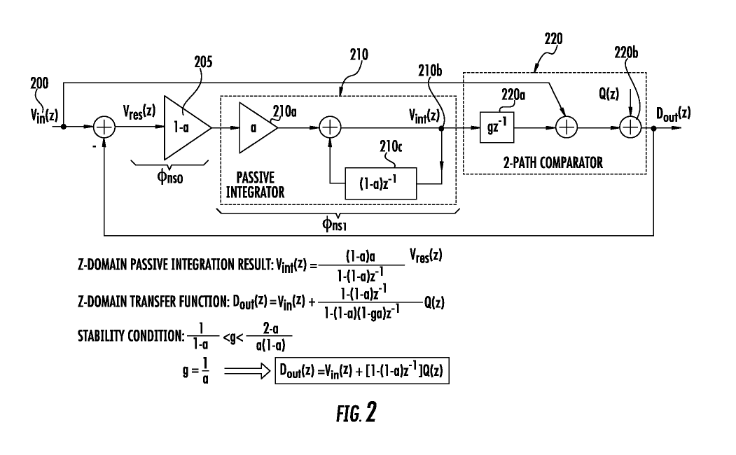

FIG. 3 investigates non-ideal effects including thermal noises and DAC mismatch errors in the flow, which except for the added noise and errors, is identical to the representation and discussion of FIG. 2. Here the only additional additions to the signal flow path are n₁ (301), n₂ (306), n₃ (311), (n₄, n₅, ε₁) 321, and ε₂ (325). Here, n₁ refers, in some embodiments, to the

$$\frac{kT}{C}$$

sampling noise which directly adds to the input signal; n₂ refer, in some embodiments, to the noise voltage on C₂ at the end of the φₙₛ_{₀} cycle; and n₃ refers, in some embodiments, to the noise voltage on C₃ at the end of the φₙₛ_{₁} cycle. FIG. 3 also shows the noise power for n₂ and n₃. With

$$a = \frac{1}{4} , \overline{{n}_{2}^{2}} = \frac{9 kT}{4 C} and \overline{{n}_{3}^{2}} = \frac{kT}{4 C}$$

(all values approximate). As shown in the Dₒᵤₜ equation (as shown in FIG. 3 and in Equation 2 reproduced below), n₁, n₂, and n₃ directly pass through without being shaped. The comparator noise n₄, the DAC noise n₅, and the quantization noise Q can be added at the same location, altogether shaped to the first-order.

$${D}_{out} ( z ) = {V}_{in} ( z ) + {n}_{1} ( z ) + {n}_{2} ( z ) {z}^{- 1} + \frac{{n}_{3} ( z )}{a} {z}^{- 1} + [ Q ( z ) + {n}_{4} ( z ) + {n}_{5} ( z ) ] [ 1 - ( 1 - a ) {z}^{- 1} ] + {ɛ}_{1} ( z ) \qquad ( Equation 2 )$$

Without wishing to be bound a particular theory, another advantage of the disclosed NS SAR ADC is its simplified digital DAC mismatch calibration. For conventional multi-bit ΔΣ ADCs, in order to completely remove the DAC mismatch error in the digital domain, one may need to accurately extract not only the DAC mismatch percentage but also the DAC mismatch error transfer function (ETF). This additional requirement can arise because the ETF may not be exactly equal to 1 due to PVT variations. As a result, special techniques such as inserting a binary pseudorandom test signal may be required to measure the ETF. By contrast, the ETF of the NS SAR ADC can be equal to 1 for any NTF under any PVT variation. One reason can be that the quantizer and the feedback DAC may use the same capacitor array in a NS SAR ADC. This may be different from conventional multi-bit ΔΣ ADCs whose DAC and quantizer are unrelated.

As shown in FIG. 3, ε₁ can represent the quantizer error due to capacitor mismatch, and ε₂ can represent the feedback mismatch error. Since they are from the same origin in the NS SAR ADC, it is possible to show that ε₂(Z)=ε₁(z). As a result, the ETF can be equal to approximately 1 regardless of the values of a and g (see the eqn. in FIG. 3). Even though capacitor mismatches may exist, in this case, it can be acceptable since the disclosed architecture can be equivalent to a NS SAR ADC that uses a non-binary DAC array. Element 335 describes the noise power value on C2 during φₙₛ_{₀} and on C3 during and the resistors model the switch-on resistances. As long as the capacitor mismatches are estimated, these mismatches can be removed in the digital domain. In the disclosed systems and methods, the NS ADC can be reconfigured in the conventional Nyquist SAR mode at first and classic foreground calibration techniques (such as those described in H. S. Lee, et al., “A Self-Calibrating 15 bit CMOS A/D Converter,” IEEE Journal of Solid-State Circuits, vol. 19, pp. 813-819, 1984, incorporated fully by reference herein) can be applied to estimate the DAC mismatch errors.

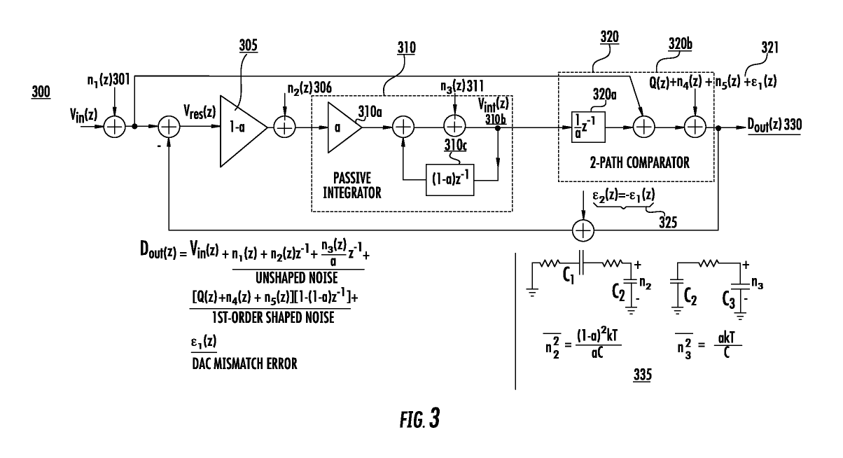

As shown in FIG. 4, a prototype first-order NS SAR ADC was fabricated in approximately 130 nm wherein the NS SAR ADC comprises complementary metal-oxide-semiconductor (CMOS) process with a core area of approximately 0.13 mm². The DAC array is approximately 10-bit with a total capacitance of approximately 1.8 pF×2. The sampling frequency is approximately 2 MS/s. At an approximately 1.2V supply, the chip consumes approximately 57 μW power, approximately 56% of which comes from the digital portion of the chip.

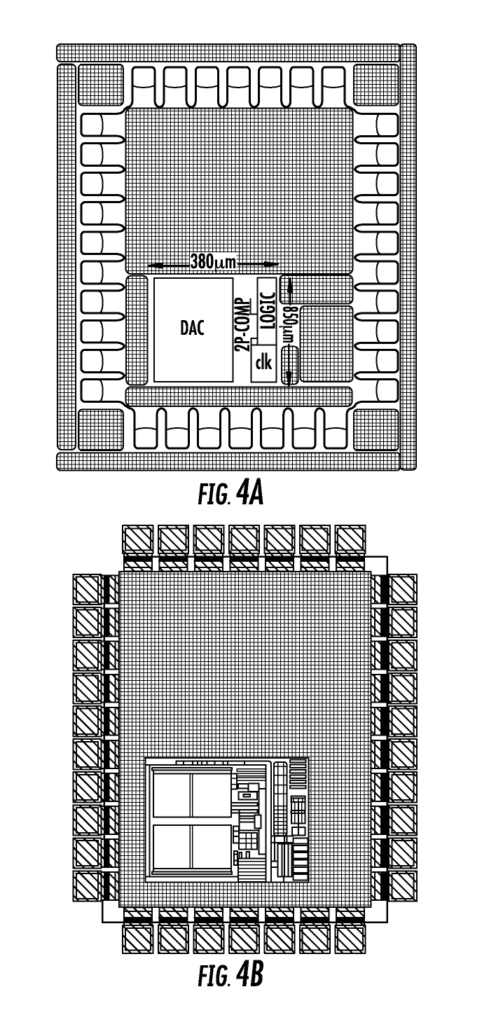

FIG. 5 shows the measured output spectrum of an exemplary NS SAR ADC with an approximately 95.37 KHz, approximately −2 dBFS sinusoidal input. After digital DAC mismatch calibration, in the conventional Nyquist SAR mode, signal-to-noise and distortion ratio (SNDR) and spurious free dynamic range (SFDR) are approximately 61.2 dB and approximately 81.6 dB, respectively. In the ΔΣ NS mode, at oversampling ratios (OSRs) of approximately 8, SNDR and SFDR are approximately 73.7 dB and approximately 95.3 dB, respectively.

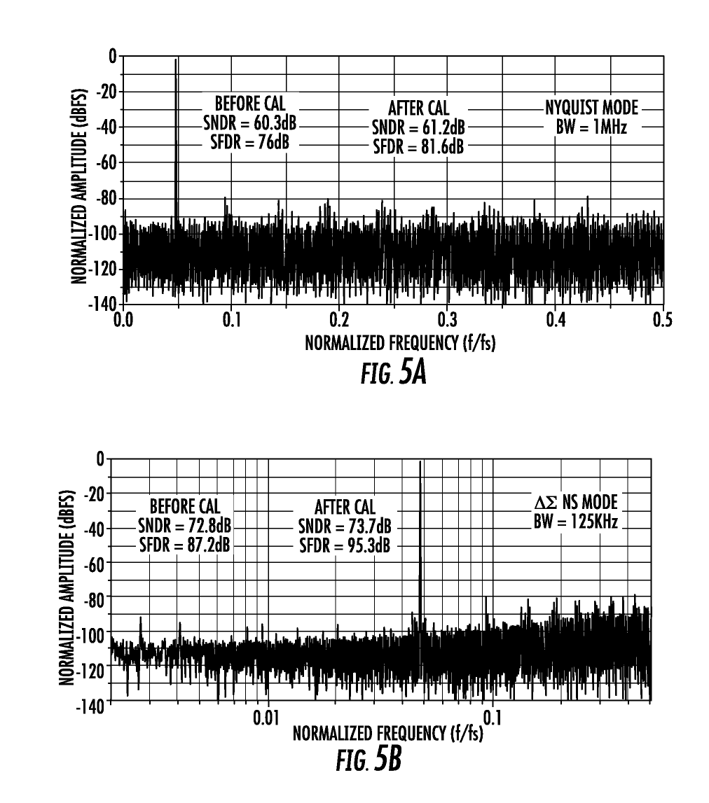

FIG. 6 shows the measured SNR/SNDR trends with different OSRs and input amplitudes in the ΔΣ NS mode. As can be seen, SNR/SNDR increases by approximately 6 dB with OSR doubled, which matches the designated NTF of approximately (1−¾z⁻¹).

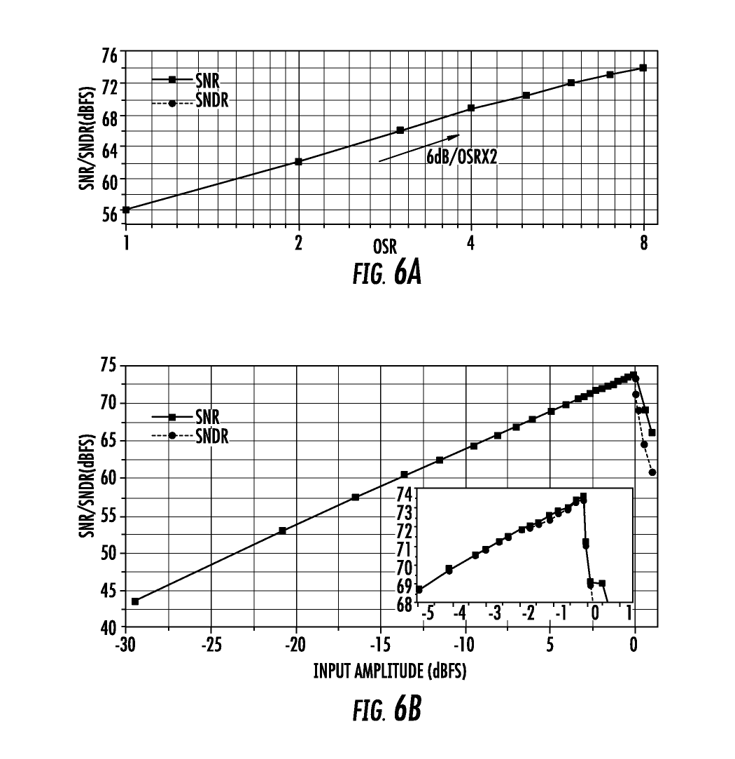

FIG. 7 summarizes the chip performance and compares it with previous NS SAR ADC works. As can be seen, the systems and methods disclosed herein can reach higher ENOB and better Schreier figure-of-merit (FoM) values (see Equation 3) in an older process technology. Moreover, because the disclosed NS SAR ADC architecture is nearly as simple as a conventional SAR ADC, its power efficiency can be greatly improved with CMOS scaling.

FoM_{S}=SNDR+10 log₁₀(BW/Power) (Equation 3)

In another aspect, the disclosed first-order NS SAR ADC can be extended to second-order noise shaping by adding an additional path to the two-path comparator and an additional passive integrator (i.e., to provide a second voltage integration loop). Based on circuit simulations, second-order noise shaping can allow an approximately 0.5-bit ENOB (effective number of bits) increase for every two-fold increase in OSR (oversampling ratios), leading to a more power efficient and high-resolution SAR ADC architecture.

The exemplified NS SAR ADC (e.g., 100, 800, and etc.) circuit can be used for various analog-to-digital conversion applications as a standalone analog to digital conversion (e.g., for industrial controls, medical devices, telecommunication devices, and etc.)

In addition to being a stand-alone ADC, the disclosed NS SAR ADCs (e.g., 100 and 800) can also be combined with front-end electronics to be used in various applications. For example, high-order continuous-time (CT) delta-sigma ADCs can be used for wireless communication applications. In this context, high-order can refer to more CT integrators being used in the NS SAR ADC architecture and a reduced need for stability control in terms of functionality. Although standalone NS SAR ADCs can work in the discrete-time domain, they can also work as a noise-shaping quantizer following a one-stage CT integrator. This can greatly relax the design complexity and loop stability control requirements with respect to conventional CT delta-sigma ADCs.

Furthermore, the disclosed NS SAR ADCs can be applied to time-to-digital converters (TDCs). TDCs were historically used in laser range-finding applications, automatic test equipment, and timing jitter measurements. Recent developments in the design of high-resolution TDCs have paved the way for mostly digital implementation of phased-lock loops (PLLs) and ADCs. Conventional NS TDCs rely on active integrators and/or ring-oscillators, which can be have high power consumption and be vulnerable to PVT variations. With time-to-voltage front end circuitry, the disclosed NS SAR ADC can be used to build a power-efficient, high-resolution TDC.

Example Second Order Noise-Shaping Successive Approximation Register ADC Architecture

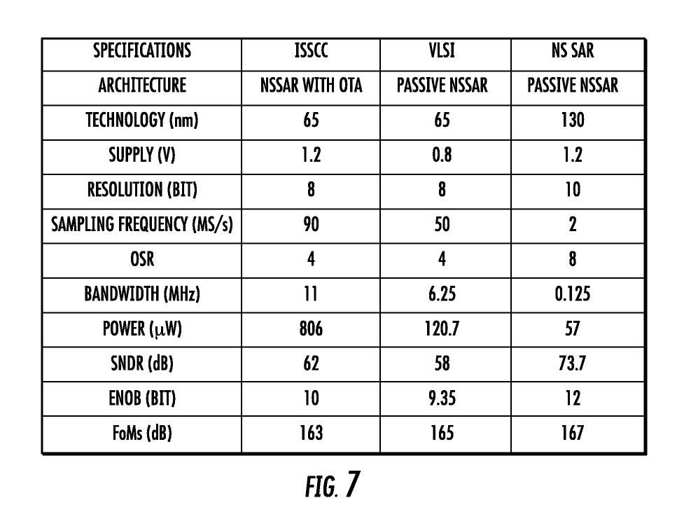

FIG. 8 shows a representative circuit diagram for a second-order NS SAR ADC 800 in accordance with an exemplary aspect of the disclosed systems and methods. As stated above, the first-order NS SAR ADC can be extended to second-order noise shaping by adding an additional path to the two-path comparator and an additional passive integrator. In FIG. 8, the NS SAR ADC 800 includes a second integrated voltage loop 802 that is implemented, in an embodiment, via an integrating capacitor (shown as “C4=C” 804), an additional 16x input path 806 to the comparator 140, and an additional noise shaping cycle Φₙₛ₂ (including a Φₙₛ₂ switch 808 and a Φₙₛ₂ clock cycle 810).

As discussed in relation to FIG. 1B, and also shown in FIG. 8, at the end of Φₙₛ₀ cycle 103d (e.g., when Φₙₛ₀ switch 117 opens), in some embodiments, C2 (122) will carry a charge. In the following Φₙₛ₁ cycle (e.g., when Φₙₛ₁ switch 123 is closed), C2 (122) dumps its charge onto another capacitor (shown as “C3=C” 124). After capacitor C2 (122) dumps Vᵣₑₛ onto C3 (124) during Φₙₛ₁, C2 further dumps the new voltage Vᵢₙₜ₁ C4 (804). The integrated voltage on C4 (804) is labelled as Vᵢₙₜ₂, which is connected to the 16× comparator input path (shown in a 3-path comparator 812).

To not slow down the NS SAR ADC with the inclusion of a second Φₙₛ₂ clock cycle 810 (e.g., by adding the noise-shaping cycle Φₙₛ₁ (103e) and Φₙₛ₂ (810) after Φₙₛ₀ (103d)), the Φₙₛ₁ (103e) and Φₙₛ₂ (810) clock cycles are invoked at the beginning of the period (e.g., shown as 814). As shown in FIG. 8, in an embodiment, Φₙₛ₁ (816) is active at the same time, or approximately the same time with sampling cycle Φₑ (103a), and Φₙₛ₂ (810) occurs at a next cycle (818) for the initial DAC settling in the SAR ADC.

The SAR logic, in some embodiments, is implementable in a synchronous manner. The master clock, in some embodiments, is divided into 16 cycles (e.g., via a 4-bit ripple counter and etc.)—in which the first cycle (of the 16 cycles) is used for sampling phase (follow by a second cycle for the DAC settling), the third cycle to fifteenth cycle is used as a clock signal for the comparator (e.g., 140, 812) for synchronous operation, and the sixteenth cycle is used to store the digital output. In some embodiments, Φₙₛ₀ is used as to invoke the storing of the digital output. In this example scheme, it is shown that the second-order NS SAR ADC 800 can operate as fast as a conventional SAR ADC.

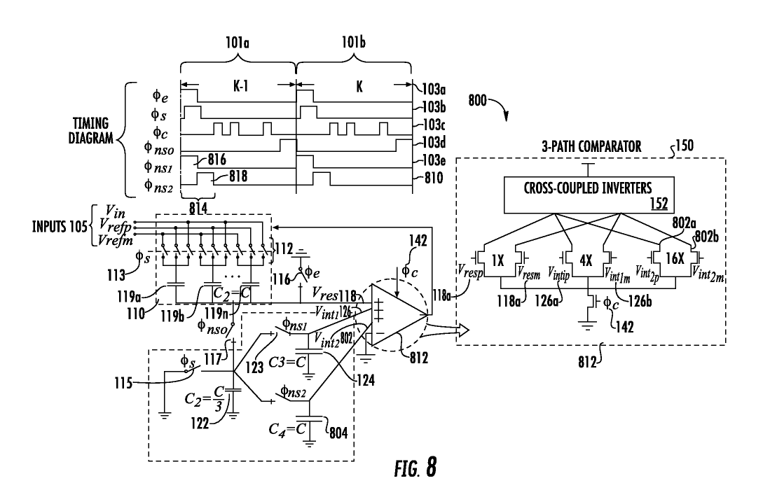

FIG. 9 shows a general signal flow diagram of the representative circuit diagram of FIG. 8. The general signal flow is shown with C1=C3=C4=C, with

$$C 2 = \frac{a}{( 1 - a ) C} ,$$

with the first integration path gain having a value of g1, and with the second integration path gain having a value of g2. It should be appreciated that other values may be used.

As shown in FIG. 9, the second integrated voltage loop 802 (shown as “passive integration 2” 902) provides a second integration loop that follows the first integrated voltage loop 126 (shown as “passive integration 1” 904) that integrates the residual voltage Vᵣₑₛ 118. The output of each loop (e.g. 906, 908) is summed with the input Vᵢₙ(z) 105.

The output transfer function Dₒᵤₜ(z) for FIG. 9 can be expressed as Equation 4. With gain g1=1/a and gain g2=1/a², Dₒᵤₜ can be simplified (see Equation 5) to only contain two zeros located at a same location (namely at location “1-a”).

$$\begin{matrix}{D}_{out} ( z ) = {V}_{in} ( z ) + \frac{{[ 1 - ( 1 - a ) {z}^{- 1} ]}^{2}}{{1 + ( 1 - a ) ( {g}_{2} {a}^{2} + {g}_{1} a - 2 ) {z}^{- 1} +}_{{( 1 - a )}^{2} ( 1 - {g}_{1} a ) {z}^{- 2}}} Q ( z ) & ( Equation 4 ) \\ {D}_{out} ( z ) = {V}_{in} ( z ) + {[ 1 - ( 1 - a ) {z}^{- 1} ]}^{2} Q ( z ) & ( Equation 5 )\end{matrix}$$

With a=¼ (for example), g1 and g2 can be reduced to g1=4 and g2=16 resulting in second order NTF of (1−0.75z⁻¹)².

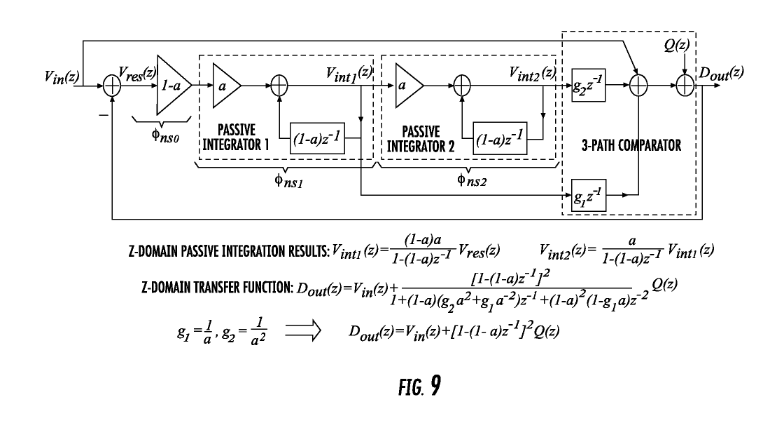

FIG. 10 shows the general signal flow diagram as in FIG. 9 with non-ideal effects such as thermal noises and DAC mismatch errors. As shown in FIG. 10, gain g1 is assumed with a value of 4 and gain g2 is assumed with a value of 16. Non-ideal effects are modelled as n₁, n₂, n₃, n₄, and n₅. Specifically, n₁ is the kT/C sampling noise which directly adds to the input signal. n₂ is the noise voltage on C2 at the end of Φₙₛ₀. n₃ is the noise voltage on C3 at the end of Φₙₛ₁. n4 is the noise voltage on C2 at the end of Φₙₛ₁. n5 is the noise voltage on C4 at the end of Φₙₛ₂.

FIG. 10 also shows the noise power for n₂, n₃, n₄, and n₅ (see 1002a, 1002b, 1002c, and 1002d). As shown in the Dₒᵤₜ equation (reproduced here as Equation 6), n₁ directly pass through without being shaped. As further shown in Equation 6, one part of n₂ is not shaped while a second part of n₂ is first-order shaped with n4. As further shown in Equation 6, one part of n₂ and n₃ is not shaped while a second part of n₂ and n₃ is first-order shaped with n₄ and n₅. As further shown in Equation 6, the comparator noise n₆, the DAC noise n₇, and the quantization noise Q are also added at a same location, altogether shaped to the second-order.

$${D}_{out} ( z ) = {V}_{in} ( z ) + {n}_{1} ( z ) + {n}_{2} ( z ) {z}^{- 1} + \frac{{n}_{3} ( z )}{a} {z}^{- 1} + [ {n}_{2} ( z ) + \frac{{n}_{3} ( z )}{a} {z}^{- 1} + \frac{{n}_{4} ( z )}{a} {z}^{- 1} + \frac{{n}_{5} ( z )}{{a}^{2}} {z}^{- 1} ] [ 1 - ( 1 - a ) {z}^{- 1} ] + {[ Q ( z ) + {n}_{6} ( z ) + {n}_{7} ( z ) ] [ 1 - ( 1 - a ) {z}^{- 1} ]}^{2} + {ɛ}_{1} ( z ) \qquad ( Equation 6 )$$

It is contemplated that higher order NS SAR ADC may be implemented using the exemplified methods and techniques. To this end, a 3^{rd}-order NS SAR ADC can be implemented by adding a third integration loop; a 4-th order NS SAR ADC can be implemented by further adding a fourth integration loop; and a N^{th} order NS SAR ADC can be implemented by adding N numbers of integration loops.

Simulation Results of Second-Order NS SAR ADC

To validate its effectiveness, a prototype second-order NS SAR ADC was designed in a 40-nm CMOS process in SPICE. The DAC array is 9-bit. To reduce the in-band thermal noise and achieve a higher ENOB, the unit capacitance value was increased by around 4 times compared to the first-order NS SAR ADC design (e.g., 100), giving a total capacitance of 4.1 pFx2. The sampling frequency is 10 MS/s. At 1.1 V supply, the simulated design consumes 95 μW power. Because digital power may increases by 3-4 times when a real chip is fabricated (e.g., due to routing parasitic capacitances), to provide for fair a comparison, the power in the simulation was increased 4 times to show the detailed power break down.

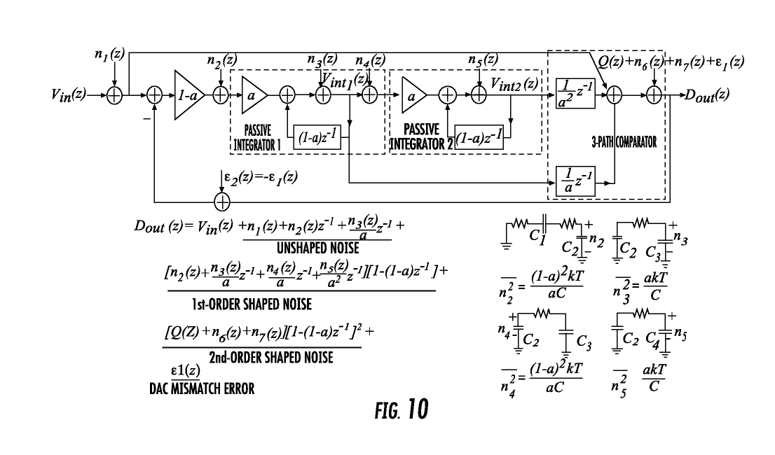

FIG. 11 shows a simulated output spectra of a second-order NS SAR ADC. As shown in FIG. 11, a simulated 256-point DFT output spectra is shown with a 117 kHz ( 3/256×10 MHz) full-scale sinusoidal input. At an OSR of 16 (approximately), SNDR and SFDR are about 88 dB and 90 dB, respectively.

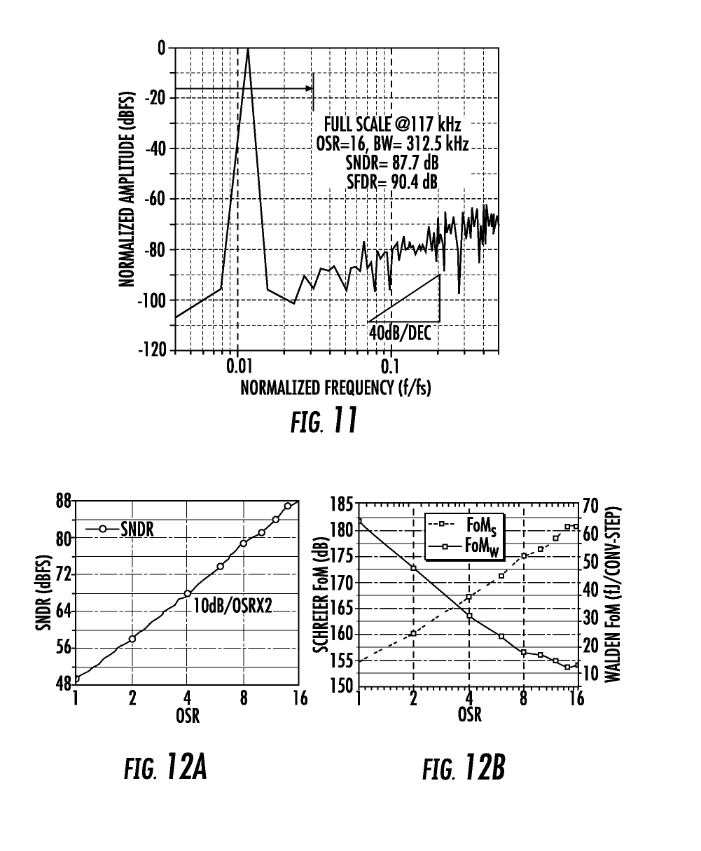

FIG. 12, comprising FIGS. 12A and 12B, shows the simulated SNDR/Schreier FoM (FoM_{S})/Walden FoM (FoM_{W}) trend with different OSRs. As shown in FIG. 12A, with OSR doubled, SNDR increases by 10 dB (approximately) which matches the NTF of (1−0.75z⁻¹)². FIG. 12B shows that the chip achieves a FoM_{S} of 181 dB and FoM_{W} of 12.5 fJ/conversion-step.

Table 1 summarizes the design performance and compares the first-order NS SAR ADC design and the second-order NS SAR ADC with a state-of-the-art Delta-Sigma ADC work disclosed in Sukumaran et al., “Low power design techniques for single-bit audio continuous delta sigma ADCs using FIR feedback,” IEEE J. Solid State Circuits, 49(11): 2515-2525 (November 2014). As shown in Table 1, by second-order noise shaping, a 9-bit SAR ADC is able to achieve 14-bit ENOB at an OSR of 16. Compared to the first-order NS SAR ADC design, the second-order design improves the FoM_{S} by 14 dB (approximately) and reduces the FoM_{W} by 4.8 times (approximately). Further, both high FoM_{S} and low FoM_{W} is achieved illustrating that second-order NS SAR ADC can reach high-resolution and high-power efficiency simultaneously.

TABLE 1

| | 1^{st} Order NS | 2^{nd} order NS SAR | Delta-Sigma |
|---|---|---|---|
| Design | SAR ADC | ADC | Comparison |
| Technology (nm) | 130 | 40 | 180 |
| Supply (V) | 1.2 | 1.1 | 1.8 |
| Resolution (bit) | 10 | 9 | 1 |
| Sampling rate (MS/s) | 2 | 10 | 6.144 |
| OSR | 8 | 16 | 128 |
| Bandwidth (kHz) | 125 | 312.5 | 24 |
| Power (μW) | 61 | 155 | 280 |
| SNDR (dB) | 74 | 87.7 | 98.2 |
| ENOB (bit) | 12 | 14.3 | 16 |
| FoMₛ (dB) | 167 | 181 | 182.3 |
| FoM_{w} (fJ/step) | 59.6 | 12.5 | 88 |

As shown in Table 1, FOMS is determined by SNDR+10 log₁₀(BW/Power) and FOMW is determined by FoM_{W}=Power/2^{ENOB}/2/BW.

### CONCLUSION

While the methods and systems have been described in connection with preferred embodiments and specific examples, it is not intended that the scope be limited to the particular embodiments set forth, as the embodiments herein are intended in all respects to be illustrative rather than restrictive.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

Throughout this application, various publications are referenced. The disclosures of these publications in their entireties are hereby incorporated by reference into this application in order to more fully describe the state of the art to which the methods and systems pertain.

It will be apparent to those skilled in the art that various modifications and variations can be made without departing from the scope or spirit. Other embodiments will be apparent to those skilled in the art from consideration of the specification and practice disclosed herein. It is intended that the specification and examples be considered as exemplary only, with a true scope and spirit being indicated by the following claims.

What is claimed is:

1. A method for noise shaping in a noise-shaping successive-approximations-register analog-to-digital converter (NS SAR ADC), comprising:
receiving a first analog input;
determining a first digital output based on the first analog input;
obtaining a first quantization error for the first digital output;
integrating the first quantization error;
receiving a second analog input; and
determining a second digital output based on the summation of the second analog input and the first integrated quantization error to perform noise-shaping.

2. The method of claim 1, wherein the NS SAR ADC comprises complementary metal-oxide-semiconductor (CMOS) technology.

3. The method of claim 1, wherein the operation of receiving the first and second analog signal further comprises sampling the first and second analog signal using a bottom-plate sampling.

4. The method of claim 1, wherein the operation of determining the second digital output based on the summation of the second analog input and the first integrated quantization error to perform noise-shaping realizes a noise transfer function (NTF) zero at a predetermined value.

5. The method of claim 4, wherein the NTF is determined in part by user configurable parameters to make the NS SAR ADC insensitive to process, voltage, temperature (PVT) variations.

6. The method of claim 1, wherein the method further allows reconfiguration between a Nyquist mode and a ΔΣ NS mode of operation.

7. The method of claim 1, wherein the operation of determining a second digital output comprises shaping a quantization noise, a comparator noise, and a DAC noise.

8. The method of claim 6, wherein a mode signal is used to reconfigure the ADC between a Nyquist mode and a ΔΣ NS mode.

9. A system for noise shaping in a NS SAR ADC, comprising:
a binary weighted capacitor array;
a two-path comparator;
a passive integrator with two capacitors;
wherein:
the binary weighted capacitor array receives a first analog input;
the two-path comparator determines a first digital output based on the analog input and obtains a first quantization error for the first digital output;
the passive integrator with two capacitors integrates the first quantization error for the first digital output to produce a first integrated quantization error;
the binary weighted capacitor array receives a second analog input; and
the two-path comparator determines a second digital output based on a summation of the second analog input and the first integrated quantization error to perform noise shaping.

10. The system of claim 9, wherein the NS SAR ADC comprises CMOS technology.

11. The system of claim 9, wherein the binary weighted capacitor array is configured to perform bottom-plate sampling.

12. The system of claim 9, wherein the two-path comparator is configured to realize a noise transfer function (NTF) zero at a predetermined value.

13. The system of claim 12, wherein the NTF is determined in part by user configurable parameters to make the NS SAR ADC insensitive to PVT variations.

14. The system of claim 9, wherein the system is reconfigurable between a Nyquist mode and a ΔΣ NS mode of operation.

15. The system of claim 9, wherein the two-path comparator is configured to shape a quantization noise, a comparator noise, and a DAC noise.

16. The system of claim 9, wherein a mode signal is used to reconfigure the ADC between a Nyquist mode and a ΔΣ NS mode.

17. A method of operating a noise-shaping successive-approximations-register analog-to-digital converter (NS SAR ADC), the method comprising:
receiving a first analog input;
determining a first digital output based on the first analog input;
obtaining a first quantization error for the first digital output;
integrating the first quantization error to generate a first integrated quantization error;
integrating the first integrated quantization error to generate a second integrated quantization error;
receiving a second analog input; and
determining a second digital output, via noise-shaping, based on the summation of the second analog input, the first integrated quantization error, and second integrated quantization error.

18. The method of claim 17, wherein the first and second integration operations are each performed via a passive integrator.

19. The method of claim 17, wherein the process of determining the second digital output is performed via a 3-path comparator circuit.

20. The method of claim 17, wherein the process of determining the second digital output is performed via an operational transconductance amplifier.
